(19) United States
(12) Patent Application Publication
(10) Pub. No.: US 2026/0237615 A1
(43) Pub. Date: Aug. 13, 2026

(54) SYSTEM AND METHOD FOR OPERATING SEMICONDUCTOR FABRICATION APPARATUS

(71) Applicants: TSMC CHINA COMPANY LIMITED, Shanghai (CN); TAIWAN SEMICONDUCTOR MANUFACTURING COMPANY, LTD., Hsinchu (TW)

(72) Inventor: Zhipeng CAO, Shanghai City (CN)

(73) Assignees: TSMC CHINA COMPANY LIMITED, Shanghai (CN); TAIWAN SEMICONDUCTOR MANUFACTURING COMPANY, LTD., Hsinchu (TW)

(21) Appl. No.: 19/068,752

(22) Filed: Mar. 3, 2025

(30) Foreign Application Priority Data
Feb. 13, 2025 (CN) 202520227177.9

(51) Int. Cl. H01J 37/32; C23C 16/40; C23C 16/44; C23C 16/455; C23C 16/50; C23C 16/52; H01L 21/02

(52) U.S. Cl. CPC H01J 37/3288; C23C 16/402; C23C 16/4408; C23C 16/45561; C23C 16/50; C23C 16/52; H01J 37/3244; H01J 2237/24455; H01J 2237/332; H10P 14/6336

(57) ABSTRACT

A method for operating a semiconductor fabrication apparatus is provided. The method includes performing a deposition process on a wafer in a process chamber; opening the process chamber; and performing a maintenance process when the process chamber is opened. The maintenance process comprises placing a gas distribution plate over a lower chamber portion of the process chamber when the process chamber is open, wherein the gas distribution plate comprises a plurality of holes; and providing a purging gas through the holes of the gas distribution plate to a space surrounded by the lower chamber portion.

### PRIORITY CLAIM AND CROSS-REFERENCE

The present application claims priority to China Application Serial Number 202520227177.9, filed Feb. 13, 2025, which is herein incorporated by reference in its entirety.

### BACKGROUND

Semiconductor devices are formed on a substrate using a manufacturing process that includes several film formation processes. Process chambers, such as chemical vapor deposition (CVD) chambers are used to process the wafers. During the film formation process, a substrate located within the CVD chamber is exposed to reactant gases introduced into the chamber and the substrate has a film deposited on it.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagrammatic top view of a semiconductor fabrication apparatus according to some embodiments of the present disclosure.

FIG. 1B is a schematic diagram of a process chamber of the semiconductor fabrication apparatus of FIG. 1A.

FIG. 2A is a schematic diagram of a detachable cleaning system applied on a lower chamber portion according to some embodiments of the present disclosure.

FIG. 2B shows an example airflow simulation of a gas flow field induced by the detachable cleaning system of FIG. 2A.

FIG. 3 is a flow chart of a method for operating a semiconductor fabrication apparatus according to some embodiments of the present disclosure.

FIGS. 4A-4F illustrates the method for operating the semiconductor fabrication apparatus of FIG. 3.

FIG. 5 shows pulses versus time for various processes when operating the semiconductor fabrication apparatus according to some embodiments of the present disclosure.

FIG. 6A is a top view of a gas distribution structure of a gas supply system according to some embodiments of the present disclosure.

FIG. 6B is a cross-sectional view of the gas distribution structure of FIG. 6A.

FIG. 7 is a cross-sectional view of a gas distribution structure of a gas supply system according to some embodiments of the present disclosure.

FIG. 8 is a cross-sectional view of a gas distribution structure of a gas supply system according to some embodiments of the present disclosure.

FIG. 9 is a top view of a gas distribution structure of a gas supply system according to some embodiments of the present disclosure.

FIG. 10 is a top view of a gas distribution structure of a gas supply system according to some embodiments of the present disclosure.

FIG. 11 shows a simulated cleaning performance (particle number versus time) of gas supply systems having gas distribution structures with different hole distributions according to some embodiments of the present disclosure.

FIG. 12 shows a simulated cleaning performance (particle number versus time) of gas supply systems having gas distribution structures with different hole path angles according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

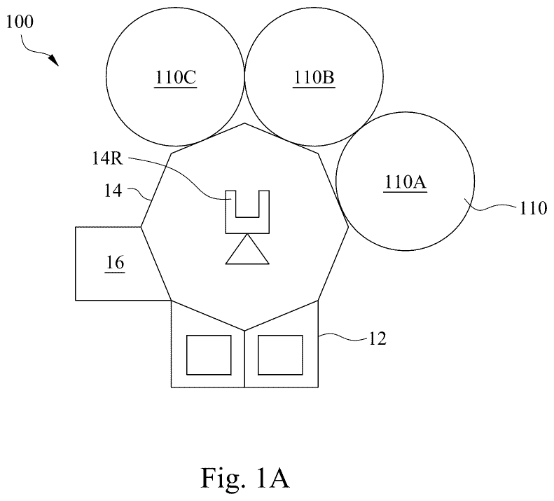

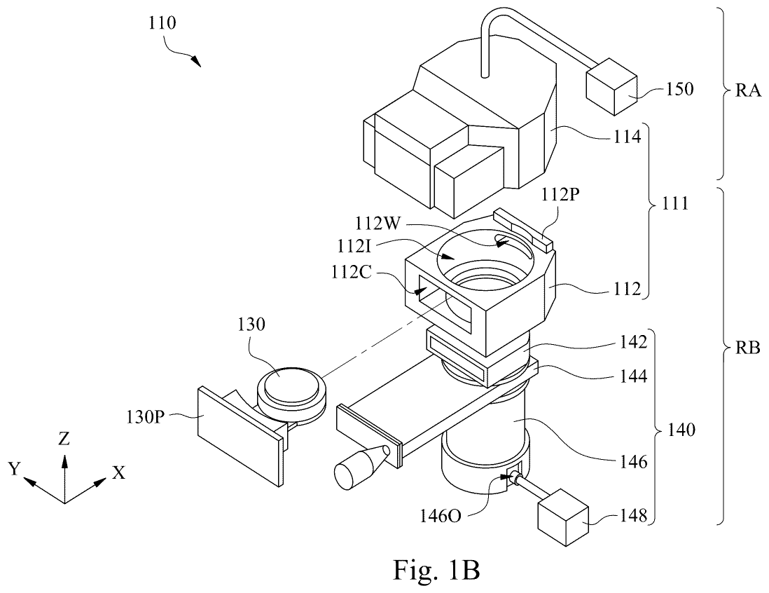

FIG. 1A is a diagrammatic top view of a semiconductor fabrication apparatus 100. In the illustrated embodiments, the semiconductor fabrication apparatus 100 includes a cluster tool, including load lock chambers 12, a wafer handling chamber 14, plural process chambers 110A-110C, an auxiliary chamber 16. The cluster tool may also include other chambers, such as wait chambers between the wafer handling chamber 14 and the load lock chambers 12 in some other embodiments. The two load lock chambers 12 may be configured for transferring wafers W into and out of the cluster tool, respectively. In various embodiments, the cluster tool (including the wafer handling chamber 14 and the process chambers 110A-110C) is under vacuum, and the load lock chambers 12 may “pump down” the wafers introduced into the cluster tool (e.g., by way of the vacuum system). In some embodiments, the load lock chambers 12 may be adapted to receive and release a single wafer or a plurality of wafers (e.g., loaded into a cassette). By way of example, the load lock chambers 12 may be separated from the wafer handling chamber 14 by way of a gate valve, allowing the wafer handling chamber 14 to remain under vacuum when one or both of the load lock chambers 12 are vented.

The wafer handling chamber 14 may also be referred to as a buffer chamber. In various embodiments, the wafer handling chamber 14 is equipped with a transfer arm 14R (e.g., robotic transfer arm). The transfer arm 14R may have a blade for holding a wafer. The transfer arm 14R may automatically move smoothly along any of a horizontal and/or vertical axis, so as to transfer wafers/substrates W between the load lock chambers 12 and any of the chambers 14.

The process chambers 110A-110C may be configured to perform a number of substrate processing operations, such as atomic layer deposition (ALD), chemical vapor deposition (CVD), physical vapor deposition (PVD), etching, film coating, pre-treatment/pre-soak, de-gassing, as well as annealing, and/or other suitable processing or operations in front-end-of-line (FEOL) or back-end-of-line (BEOL) process. For example, one or more of the process chambers 110A-110C may be configured to deposit various dielectric layers, coat an anti-reflection layer, thermally pre-treat the wafers, and/or other suitable processing or operations. In various embodiments, the cluster tool may have more or less process chambers, for example, for a desired process to be performed by the cluster tool.

The auxiliary chamber 16 may temporally keep the wafers before, during, or after the processes of the process chambers 110A-110C. In some embodiments, the auxiliary chamber 16 may be equipped with a cooling system for cooling down the wafers, and the auxiliary chamber 16 may be referred to as a cool-down chamber.

In the semiconductor fabrication process conducted by the semiconductor fabrication apparatus 100, a wafer may be transferred from one of the load lock chambers 12 to the process chamber 110A (e.g., via the wafer handling chamber 14) for being subjected to a first process. In some embodiments, the cluster tool may further include an orientor chamber, and the wafer moved from said one of the load lock chambers 12 may be oriented in the orientor chamber (not shown) first, prior to entering the process chamber 110. In some embodiments, the wafer may be transferred from the process chamber 110A to the process chamber 110B (e.g., via the wafer handling chamber 14) for being subjected to a second process, and/or the wafer may then be transferred from the process chamber 110B to the process chamber 110C (e.g., via the wafer handling chamber 14) for being subjected to a third process. In some embodiments, after the first, second, and/or third processes, the wafer may then be transferred from the process chambers 110A-110C to the auxiliary chamber 16 (e.g., via the wafer handling chamber 14) for being cooled down. The wafer that is processed through the first, second, and/or third processes, may be transferred to the other of the load lock chambers 12 for exiting the cluster tool. In the context, the process chambers 110A-110C may be referred to process chambers 110.

FIG. 1B is a schematic diagram of a process chamber 110 of the semiconductor fabrication apparatus 100 of FIG. 1A. In some embodiments of the present disclosure, the process chamber 110 can be operated with low, medium and high power HDP/CVD processes. High power processes may use power above about 15 kW, for example from 15 kW to 18 kW. Medium power processes may use power with a range from about 8 to 12 kW. Low power processes may use under about 8 kW. In some embodiments, the coils described herein below can be used to provide high power processes with voltages applied to coils. FIG. 1B schematically illustrates the structure of an exemplary HDP-CVD system in some embodiment.

The process chamber 110 includes a body 111 comprising a lower chamber body 112 and an upper chamber body 114, a wafer chuck 130, a vacuum system 140, and a gas delivery system 150. In the context, the lower chamber body 112, the wafer chuck 130, and the vacuum system 140 in combination may be referred to as a lower chamber portion RB. And, the upper chamber body 114, the gas delivery system 150, and a plasma generation system mounted on the upper chamber body 114 in combination may be referred to as an upper chamber portion RA.

The body 111 of the process chamber 110 comprises the lower chamber body 112 and the upper chamber body 114 may surround a space 110I for semiconductor process. The upper chamber body 114 may be pivotally coupled with a pivot 112P of the lower chamber body 112. The pivot 112P may extend along a direction Y, such that the upper chamber body 114 can be rotated in the plane of directions X and Z with respect to the direction Y. The directions X, Y, and Z may be orthogonal to each other. By rotating the upper chamber body 114 with respect to the pivot 112P of the lower chamber body 112, the process chamber 110 can be opened or closed. Stated differently, the upper chamber body 114 may have opposite first and second ends, the first end of the upper chamber body 114 is pivotally coupled with the pivot 112P, and the second end of the upper chamber body 114 can be moved to contacting the lower chamber body 112 or not. When the process chamber 110 is closed, the second end of the upper chamber body 114 is moved to be in contact with the lower chamber body 112. At this same, the lower chamber body 112 and the upper chamber body 114 collectively surround a space for the HDP/CVD processes. When the process chamber 110 is opening, the second end of the upper chamber body 114 is moved to be spaced apart from the lower chamber body 112. At this same, a chamber space 112I surrounded by the lower chamber body 112 is exposed.

The wafer is transferred into and out of chamber 100 by a robot blade (e.g., the robot arm 140R) through an insertion/removal opening 112W of the lower chamber body 112. The wafer chuck 130 for holding the wafer is mounted in the lower chamber body 112. The wafer chuck 130 may be moved along the direction X and inserted into the lower chamber body 112 through the channel 112C of the lower chamber body 112. The wafer chuck 130 may be an electrostatic chuck that secures the wafer during substrate processing. In some embodiments, the wafer chuck 130 has a cathode therein for providing a substrate bias to the wafer during the HDP/CVD processes. The wafer chuck 130 may be physically connected with a plate 130P, which may cover the channel 112C of the lower chamber body 112 when the wafer chuck 130 is inserted into the lower chamber body 112.

The vacuum system 140 may be fluidly connected with the lower chamber body 112, thereby allowing the chamber space 112I surrounded by the lower chamber body 112 and the upper chamber body 114 to remain under vacuum when the process chamber 110 is closed. The vacuum system 140 may include a throttle body 142, a gate body 144, a pump body 146, and a vacuum source 148. The throttle body 142 may houses a throttle valve, such as a twin-blade throttle valve. The throttle valve can adjust an amount of an exhaust gas flow that pass it through. The throttle body 142 may have an opening 142O and a cover 142C covering the opening 142O, in which the throttle valve is placed in the throttle body 142 through the opening 142O. The gate body 144 may houses a gate valve, which can control the exhaust gas flow pass itself or not. The pump body 146 may house a turbo-molecular pump. When the gate valve of the gate body 144 is opened, the turbo-molecular pump of the pump body 146 is fluidly connected with the throttle body 142. When the gate valve of the gate body 144 is closed, the gate valve of the gate body 144 can isolate the turbo-molecular pump of the pump body 146 from throttle body 142. The gate valve of the gate body 144 can control a chamber pressure by restricting the exhaust flow capacity when the throttle valve of the throttle body 142 is fully open. The vacuum source 148 may be fluidly coupled with an outlet 146O of the pump body 146 for exhausting the gas (e.g., reactant gases) during the semiconductor process. In some embodiments, the vacuum source 148 can be detached from the outlet 146O of the pump body 146 for maintaining purpose.

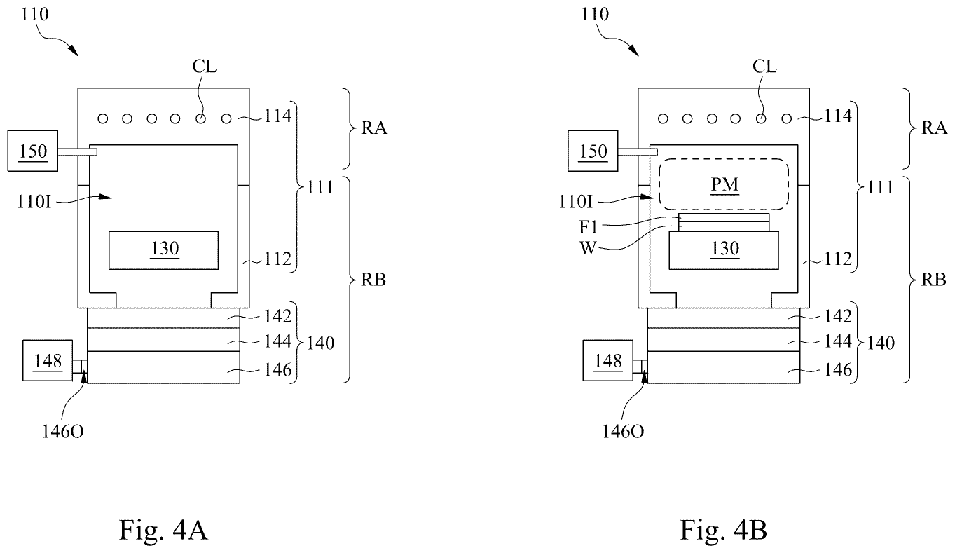

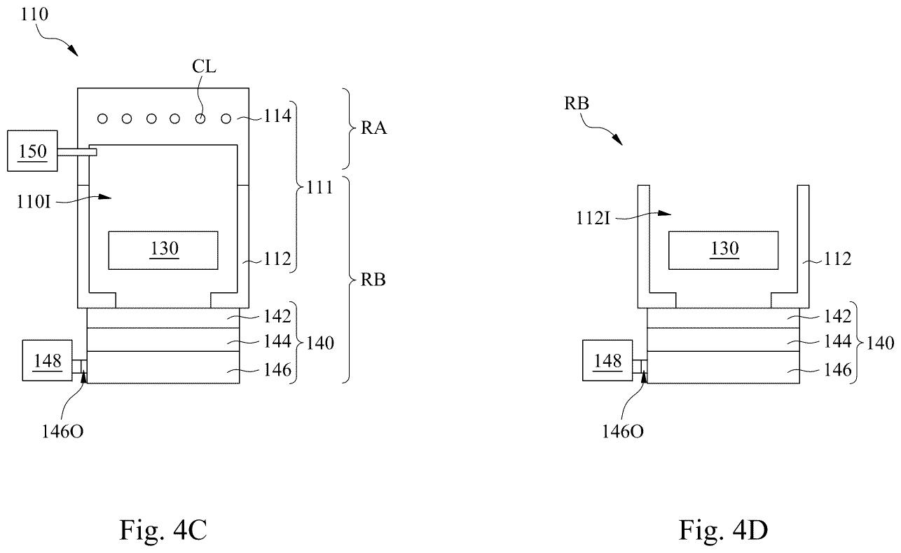

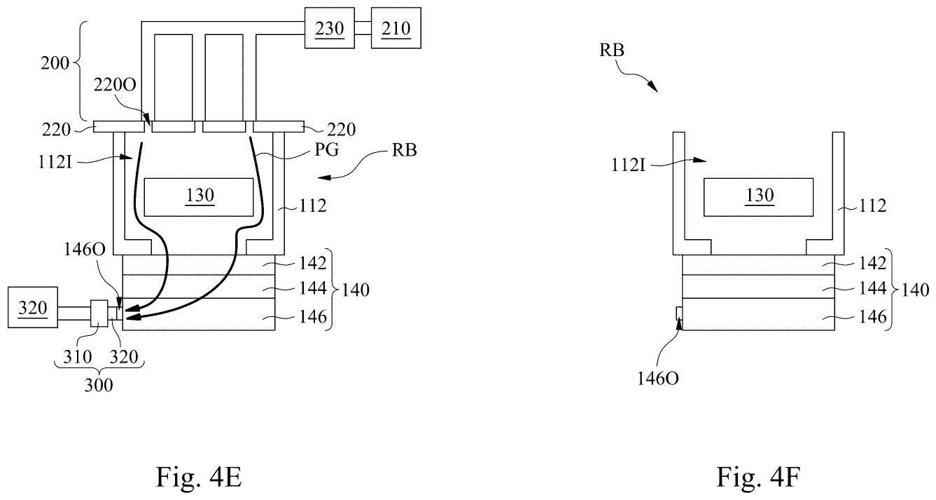

The gas delivery system 150 may be fluidly connected with the upper chamber body 114 for introducing reactant gases into the space surrounded by the lower chamber body 112 and the upper chamber body 114. For example, the gas delivery system 150 may be fluidly connected with one or more nozzles in the upper chamber body 114. In some embodiments, the upper chamber body 114 may have a plasma generation system (e.g., a coil in FIGS. 4A-4E later and a radio frequency (RF) power coupled with the coil), thereby turning the reactant gases into plasma for the HDP/CVD processes. In some embodiments, the upper chamber body 114 may include a dome made of a ceramic dielectric material, such as aluminum oxide or aluminum nitride, sapphire, SiC, or quartz.

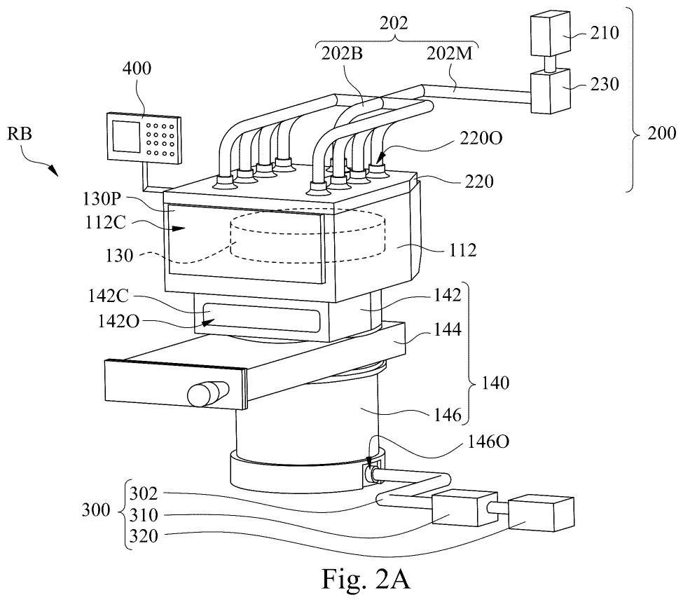

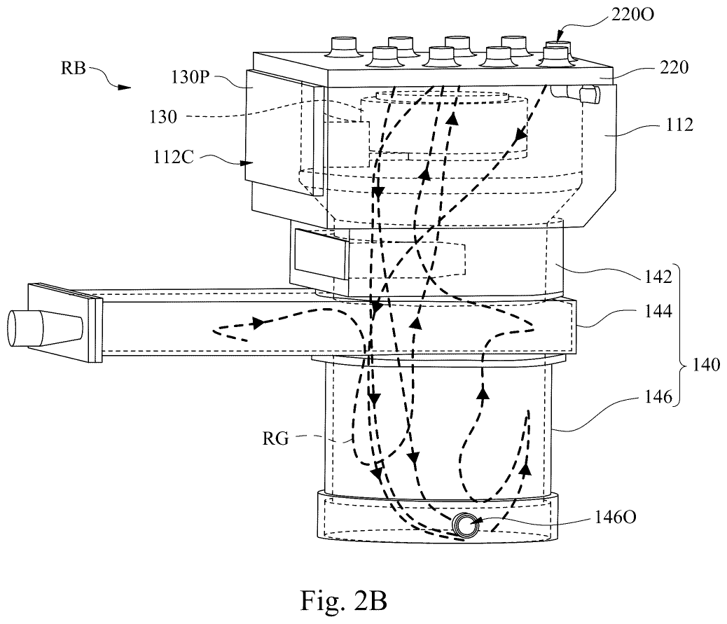

FIG. 2A is a schematic diagram of a detachable cleaning system applied on the lower chamber portion RB according to some embodiments of the present disclosure. The detachable cleaning system may include a detachable gas supply system 200, a detachable gas exhaust system 300, and a controller 400.

The gas supply system 200 may include pipes 202, a gas source 210, a gas distribution plate 220, and a pressure controller 230. The gas supply system 200 may be referred to as a gas purging system or a gas flush system in some embodiments. The gas distribution plate 220 is placed on the lower chamber body 112. The gas distribution plate 220 may be made of suitable rigid material, such as aluminum. The gas source 210 stores suitable purging gas, such as Ar, nitrogen, other clean dry air (CDA), the like, or the combination thereof. The gas distribution plate 220 has plural holes 220O allowing purging gas entering the space surrounded by the lower chamber body 112. The pipes 202 are fluidly coupled between the gas source 210 and the holes 220O of the gas distribution plate 220, thereby introducing the purging gas into the space 112I (referring to FIG. 1B) surrounded by the lower chamber body 112 through the holes 220O. For example, the pipes 202 have a distribution pipe 202M and plural branch pipes 202B branching off from the distribution pipe 202M. The distribution pipe 202M has one terminal coupled with the pressure controller 230 for gas fitting. The branch pipes 202B have terminals coupled with the holes 220O, respectively. The pressure controller 230 is fluidly coupled between the gas source 210 and the pipes 202 for adjusting a gas force of the purging gas.

The detachable gas exhaust system 300 may include a pipe 302, a particle detector 310, and a gas extractor 320. In some embodiments, the gas extractor 320 may be a pump, such as vacuum pump. During a maintenance process, the vacuum source 148 is detached from the outlet 146O of the pump body 146, and the pipe 302 fluidly connects the gas extractor 320 to the outlet 146O of the pump body 146. In some embodiments, the outlet 146O of the pump body 146 may be considered as an outlet of the lower chamber portion RB. The particle detector 310 is fluidly coupled with the pipe 302 between the gas extractor 320 and the outlet 146O of the pump body 146. The particle detector 310 counts the number of particles per liter of gas flow. The purging gas, provided by the gas supply system 200, passes from the chamber space 112I surrounded by the lower chamber body 112, through the throttle body 142, the gate body 144, and the pump body 146 to the particle detector 310, and then through the gas extractor 320 which provides the suction force to draw/extract the gas from the pump body. Through the configuration, the interior of the lower chamber portion RB (e.g., interiors of the lower chamber body 112, the throttle body 142, the gate body 144, and the pump body 146) is flushed with the purging gas. Through the configuration, the components in the chamber space 112I (e.g., the wafer chuck 130), the components in the throttle body 142 (e.g., the throttle valve), the components in the gate body 144 (e.g., the gate valve), and the components in the pump body 146 (e.g., the turbo-molecular pump) are flushed with the purging gas.

The controller 400 is communicatively connected with the detachable gas supply system 200 and the detachable gas exhaust system 300, and the controller 400 is capable of controlling the operation of the detachable gas supply system 200. For example, the controller 400 is communicatively connected with the particle detector 310 and the pressure controller 230. Through the configuration, the controller 400 may receive data of a particle number from the particle detector 310 and control the pressure controller 230 to adjust the gas force of the purging gas according to the data. The controller 400 may include a computer-readable storage medium and a processer coupled with the computer-readable storage medium. The computer-readable storage medium is configured to store data and processing instructions and a process coupled with the computer-readable storage medium. The processer is configured to retrieve and execute the processing instructions stored in the computer-readable storage medium. In some embodiments, the computer-readable storage medium may be a computer-readable medium, such as random access memory (RAM), read only memory (ROM), floppy disk, hard disk, flash memory or any other suitable form of digital storage. In some embodiments, the processor may be a general purpose processor, a multi-core processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

FIG. 2B shows an example airflow simulation of a gas flow field induced by the detachable cleaning system of FIG. 2A. Using the detachable cleaning system, the purging gas PG is introduced into the lower chamber body 112, the throttle body 142, the gate body 144, and the pump body 146 of the lower chamber portion RB. The paths of the purging gas PG are illustrated as the gas flow field. The purging gas PG may exit the pump body 146 through the outlet 146O of the pump body 146.

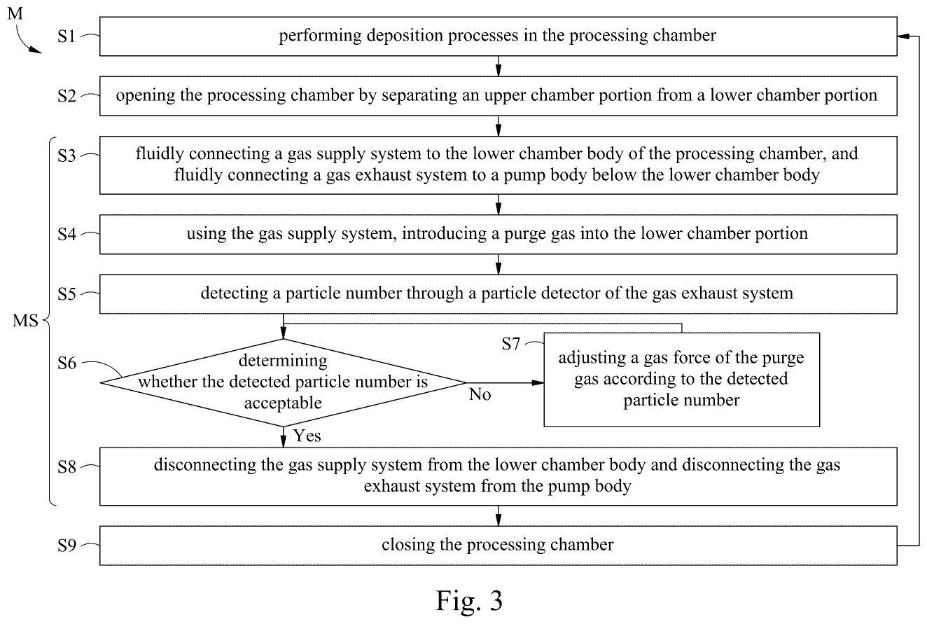

FIG. 3 is a flow chart of a method for operating a semiconductor fabrication apparatus according to some embodiments of the present disclosure. FIGS. 4A-4F illustrates the method for operating the semiconductor fabrication apparatus of FIG. 3. The method M includes steps S1-S9. It is understood that additional steps may be provided before, during, and after the steps S1-S9 shown in FIG. 3, and some of the steps described below can be replaced or eliminated for additional embodiments of the method. The order of the operations/processes may be interchangeable. Steps S3-S8 in combination may be referred to as a maintenance step MS.

The method M begins at step S1, where one or more deposition processes are performed in the process chamber 110. The deposition processes may be a high-plasma deposition process. Prior to a deposition process, referring to FIG. 3 and FIG. 4A, a wafer W is moved into the process chamber 110, for example, being placed onto the wafer chuck 130. After moving a wafer W into the process chamber 110 (e.g., placing the wafer W onto the wafer chuck 130), referring to FIG. 3 and FIG. 4B, at step S1, the gas delivery system 150 may introduce reactant gases into the space 110I surrounded by the lower chamber body 112 and the upper chamber body 114. And, the coil CL in the upper chamber body 114 may be applied with a RF power, thereby turning the reactant gases into plasma PM for depositing film (e.g., SiO₂ films) F1 over the wafer W. After depositing the film F1 over the wafer W, referring to FIG. 3 and FIG. 4C, the wafer W is moved out of the process chamber 110 (e.g., moving the wafer away from the wafer chuck 130). After repeating the steps of FIGS. 4A-4C for performing the deposition processes on various wafers (e.g., as the pulses of the deposition process in FIG. 3), the method M proceeds to the maintenance step MS.

Reference is made to FIG. 3 and FIG. 4D. The method M proceeds to step S2 of the maintenance step MS, where the process chamber 110 is open by separating an upper chamber portion RA (referring to FIG. 4C) from a lower chamber portion RB. For example, the interior of the chamber body 112 is exposed.

Reference is made to FIG. 3 and FIG. 4E. The method M proceeds to step S3 of the maintenance step MS, where a gas supply system 200 is fluidly connected to the lower chamber body 112 of the lower chamber portion RB, and a gas exhaust system 300 is fluidly connected to the pump body 146 below the lower chamber body 112 of the lower chamber portion RB.

The method M then proceeds to step S4 of the maintenance step MS, where the gas supply system 200 is used to introduce a purging gas PG into the lower chamber portion RB. The purging gas PG may flush the chamber space 112I surrounded by the lower chamber body 112, the throttle body 142, the gate body 144, and the pump body 146. The gas exhaust system 300 is configured to draw the purging gas PG and particles away from the chamber space 112I surrounded by the lower chamber body 112, the throttle body 142, the gate body 144, and the pump body 146.

The method M proceeds to step S5, where a particle number is detected through a particle detector 310 of the gas exhaust system 300 when the purging gas PG is introduced into the chamber space 112I by the gas supply system 200 and the purging gas PG is draw by the gas exhaust system 300.

The method M proceeds to step S6, where a determination is made to determine whether the detected particle number is acceptable. The determination step may include comparing the detected particle number to a threshold particle number. In some examples, the threshold particle number may be in a range from about 0 to about 100. When the detected particle number is greater than the threshold particle number, the detected particle number is determined to be unacceptable, and the method proceeds to step S7, where a gas force of the purge gas is adjusted according to the detected particle number. For example, when the detected particle number is in a first range, the pressure controller 230 may tune the gas force of the purge gas PG to be introduced to be a first gas force. And, when the detected particle number is in a second range greater than the first range, the pressure controller 230 may tune the gas force of the purge gas PG to be introduced b a second gas force greater than the first gas force. Thus, the purge gas PG can be introduced by a suitable gas force according to the contamination condition of the chamber space 112I, the throttle body 142, the gate body 144, and the pump body 146.

The steps S6 and S7 may be repeated until the detected particle number is acceptable. When the detected particle number is less than the particle number, the detected particle number is determined to be acceptable, and the maintenance/cleaning process is finished/stopped/terminated. For example, the act of flushing the interior of the lower chamber portion RB (e.g., the interiors of the lower chamber body 112, the throttle body 142, the gate body 144, and the pump body 146) is terminated. After the maintenance/cleaning process is finished/stopped/terminated, referring to FIG. 4F, the method M proceeds to step S8, where the gas supply system 200 is disconnected from the lower chamber body 112, and the gas exhaust system 300 is disconnected from the pump body 146.

Reference is made to FIG. 3 and back to FIG. 4A. The method M proceeds to step S9, where the process chamber 110 is closed by moving the upper chamber portion RA back to a position over the lower chamber portion RB. The method M may then go back to step S1 for performing one or more deposition processes in the process chamber 110.

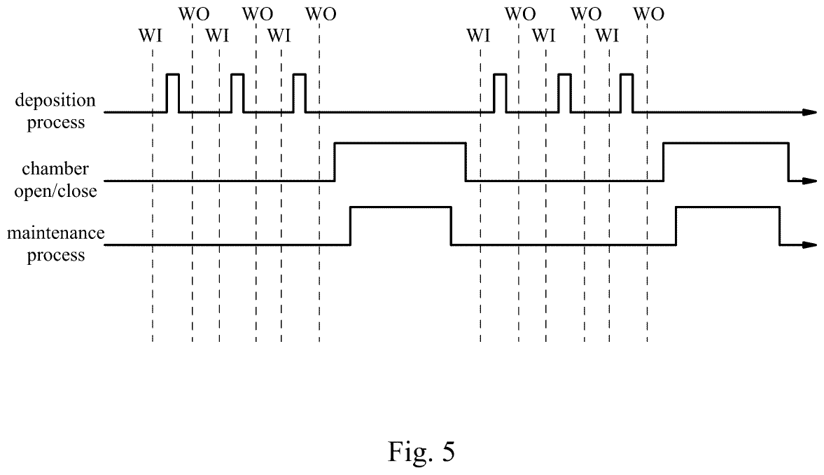

FIG. 5 shows pulses versus time for various processes when operating the semiconductor fabrication apparatus according to some embodiments of the present disclosure. In FIG. 5, dashed lines WI and WO are used to indicate the timings of wafer transfer. The dashed lines WI indicate the timing when the wafer is moved onto a wafer chuck 130 (referring to FIG. 4A). And, the dashed lines WO indicate the timing when the wafer is moved away from the wafer chuck 130 (referring to FIG. 4C). As shown in FIG. 5, wafers are transfer into and out of a process chamber 110 for depositing films thereon (e.g., the step S1 in FIG. 3). After performing several deposition processes in the process chamber 110 on the wafers, the process chamber 110 is open (e.g., the step S2 in FIG. 3), and a maintenance process (e.g., the maintenance step MS in FIG. 3) is performed. After the maintenance process (e.g., the maintenance step MS in FIG. 3), the process chamber 110 is closed (e.g., the step S9 in FIG. 3).

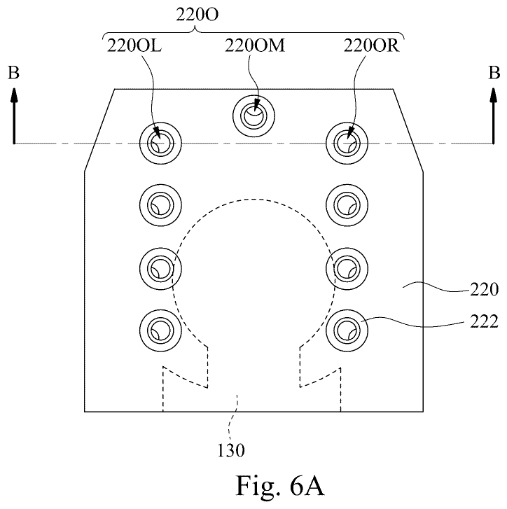

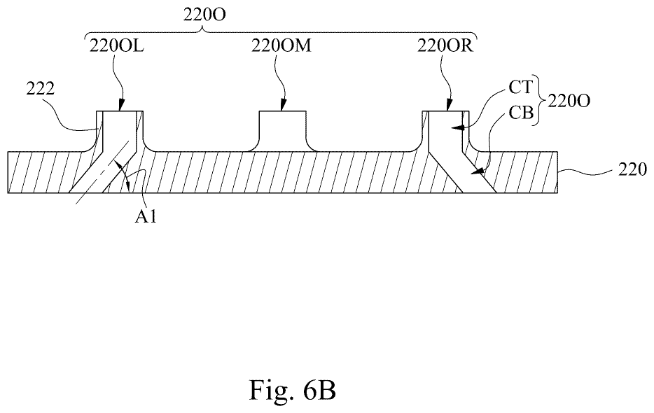

FIG. 6A is a top view of a gas distribution structure 220 of a gas supply system according to some embodiments of the present disclosure. FIG. 6B is a cross-sectional view of the gas distribution structure 220 of FIG. 6A. The gas distribution structure 220 may include plural holes 220O extending from a top surface of the gas distribution structure 220 to a bottom surface of the gas distribution structure 220. The holes 220O allows the purging gas to pass the gas distribution structure 220, and enter the chamber space surrounded by the lower chamber portion. In the present embodiments, the holes 220O may be free of overlapping the wafer chuck 130 in the top view. For example, the holes 220O may be separated/spaced apart from the wafer chuck 130 in the top view. Through the configuration, the purging gas introduced through the gas distribution structure 220 may not be blocked by the wafer chuck 130, thereby facilitate the clean efficiency.

In the present embodiments, the holes 220O may be designed with suitable angles for injecting the purging gas into the space surrounded by the lower chamber portion. For example, the gas distribution structure 220 has plural raised portions 222 raising from a top surface of the plate body of the gas distribution structure 220, and each of the holes 220O has a top hole CT in the raised portion 222 and a bottom hole CB in the plate body of the gas distribution structure 220. The bottom hole CB is fluidly communicated with the top hole CT. In some embodiments, the top hole CT may extend in the raised portion 222 in a direction Z perpendicular to a bottom surface of the gas distribution structure 220 (e.g., the plane of directions X and Y). In some embodiments, the directions X, Y, and Z are substantially orthogonal to each other. In some embodiments, the bottom hole CB may extend in the plate body of the gas distribution structure 220 in a direction having an angle A1 tilted with respect to the bottom surface of the gas distribution structure 220 (e.g., the plane of the directions X and Y). The angle A1 may be in a range from about 20 degrees to about 90 degrees. For example, in the present embodiments, the angle A1 in a range from about 40 degrees to about 50 degrees.

In the present embodiments, the bottom holes CB of the holes 220O may respectively extend in various directions for providing suitable gas flow fields. For clear illustration, in FIG. 6A, the holes 220O of a left column in the direction Y are referred to as holes 220OL, the holes 220O of a right column in the direction Y are referred to as holes 220OR. And, the hole 220O between the holes 220OL and through 220OR is referred to as a hole 220OM. In the present embodiments, the extension direction of the bottom holes CB of the holes 220OR, the extension direction of the bottom holes CB of the holes 220OL, and the extension direction of the bottom holes CB of the hole 220OM are different from each other. For example, the bottom holes CB of the holes 220OL tilt towards a direction opposite to the direction X, the bottom holes CB of the holes 220OR tilt towards the direction X, and the bottom holes CB of the holes 220OM tilt towards the direction Y. In some embodiments, the extension direction of the bottom holes CB of the holes 220OL is at the plane of the direction X and Z and has the angle A1 tilted with respect to the bottom surface of the gas distribution structure 220 (e.g., the plane of the directions X and Y). In some embodiments, the extension direction of the bottom holes CB of the holes 220OR is at the plane of the direction X and Z and has the angle A1 tilted with respect to the bottom surface of the gas distribution structure 220 (e.g., the plane of the directions X and Y). In some embodiments, the extension direction of the bottom holes CB of the hole 220OM is at the plane of the direction Y and Z and the angle A1 tilted with respect to the bottom surface of the gas distribution structure 220 (e.g., the plane of the directions X and Y).

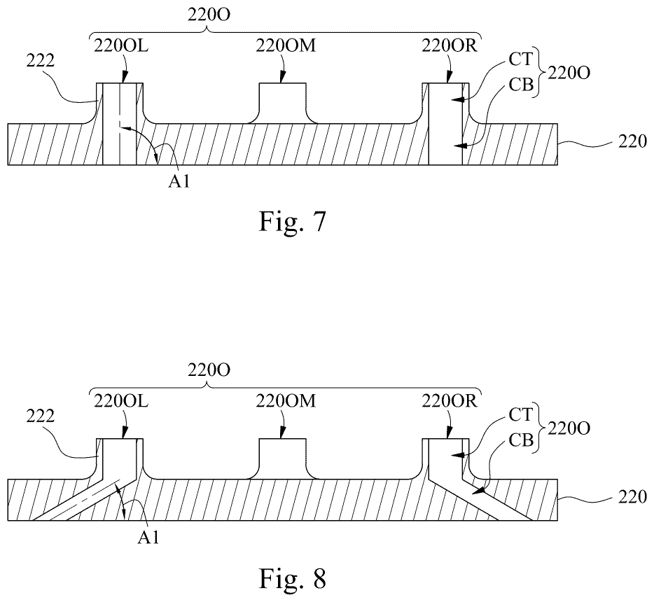

FIG. 7 is a cross-sectional view of a gas distribution structure 220 of a gas supply system according to some embodiments of the present disclosure. Details of the present embodiments are similar to those of the embodiments of FIG. 6B, except that the angle A1 is in a range from about 80 degrees to about 90 degrees. For example, the extension directions of the bottom holes CB of the holes 220OL, the holes 220OR, and the hole 220OM is substantially perpendicular to the bottom surface of the gas distribution structure 220 (e.g., the plane of the directions X and Y). Other details of the present embodiments are similar to those of the embodiments of FIG. 6A, and thereto not repeated herein.

FIG. 8 is a cross-sectional view of a gas distribution structure 220 of a gas supply system according to some embodiments of the present disclosure. Details of the present embodiments are similar to those of the embodiments of FIG. 6B, except that the angle A1 is in a range from about 20 degrees to about 40 degrees. Other details of the present embodiments are similar to those of the embodiments of FIG. 6A, and thereto not repeated herein.

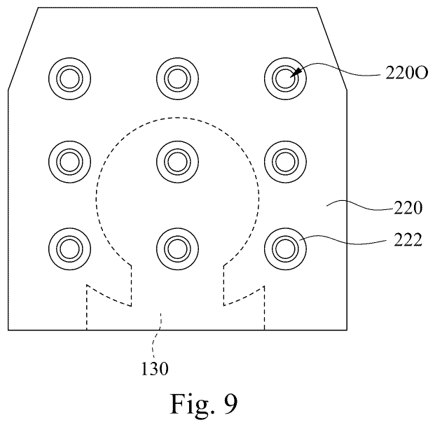

FIG. 9 is a top view of a gas distribution structure 220 of a gas supply system according to some embodiments of the present disclosure. Details of the present embodiments are similar to those of the embodiments of FIG. 6A, except that some of the holes 220O of the gas distribution structure 220 may vertically overlap the wafer chuck 130. In the present embodiments, the holes 220O of the gas distribution structure 220 may be arranged in an array. For example, the holes 220O of the gas distribution structure 220 are arrayed with 3 columns and 3 rows. The holes 220O in a same row are aligned with each other along the direction X, and the holes 220O in a same column are aligned with each other along the direction Y. In some embodiments, the holes 220O are symmetric about a central point. Other details of the present embodiments are similar to those of the embodiments of FIG. 6A, and thereto not repeated herein.

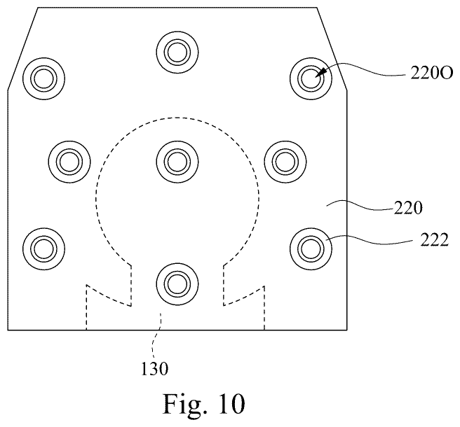

FIG. 10 is a top view of a gas distribution structure 220 of a gas supply system according to some embodiments of the present disclosure. Details of the present embodiments are similar to those of the embodiments of FIG. 9, except that every two adjacent ones of the holes 220O may be misaligned with each other along the direction X, and every two adjacent ones of the holes 220O may be misaligned with each other along the direction Y. Other details of the present embodiments are similar to those of the embodiments of FIG. 9, and thereto not repeated herein.

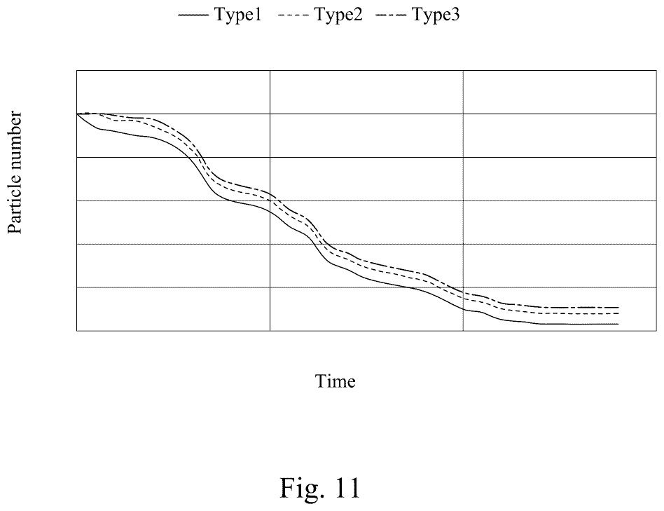

FIG. 11 shows a simulated cleaning performance (particle number versus time) of gas supply systems having gas distribution structures with different hole distributions according to some embodiments of the present disclosure. The horizontal axis is time after fluidly connecting the gas supply system to the lower chamber portion RB, and the vertical axis is a particle number detected by the particle sensor. A curve “Type 1” indicates the cleaning performance using the gas distribution plate 220 having a distribution of the holes 220O as shown in FIG. 6A. A curve “Type 2” indicates the cleaning performance using the gas distribution plate 220 having a distribution of the holes 220O as shown in FIG. 9. A curve “Type 3” indicates the cleaning performance using the gas distribution plate 220 having a distribution of the holes 220O as shown in FIG. 10. From the curves “Type 1,” “Type 2,” and “Type 3,” it is evidenced that the particle number can be lowered by using the gas supply system.

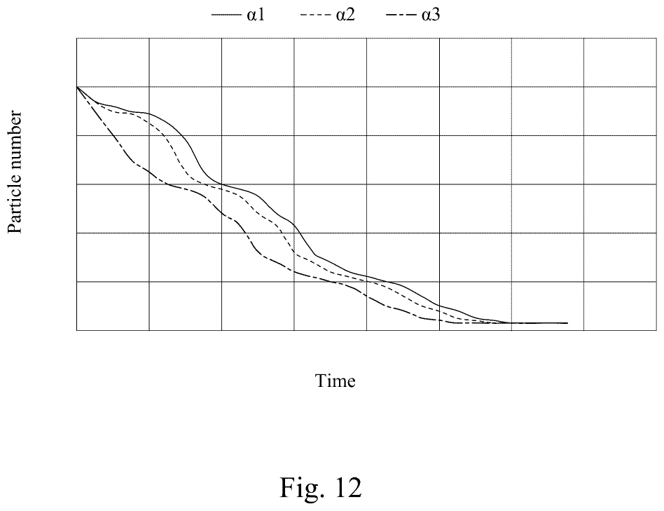

FIG. 12 shows a simulated cleaning performance (particle number versus time) of gas supply systems having gas distribution structures with different hole path angles according to some embodiments of the present disclosure. The horizontal axis is time after fluidly connecting the gas supply system to the lower chamber portion RB, and the vertical axis is a particle number detected by the particle sensor. A curve “α1” indicates the cleaning performance using the gas distribution plate 220 having holes 220O with an angle A1 in a range from about 80 degrees to about 90 degrees, as shown in FIG. 7. A curve “α2” indicates the cleaning performance using the gas distribution plate 220 having holes 220O with an angle A1 in a range from about 20 degrees to about 40 degrees, as shown in FIG. 8. A curve “α3” indicates the cleaning performance using the gas distribution plate 220 having holes 220O with an angle A1 in a range from about 40 degrees to about 50 degrees, as shown in FIG. 6B. From the curves “α1,” “α2,” and “α3,” it is evidenced that the particle number can be lowered by using the gas supply system.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by connecting the gas supply system to the lower chamber body and connecting the gas exhaust system to the outlet of the pump body, the particles in the lower chamber portion (e.g., in the lower chamber body, the throttle body, the gate body, and the pump body) can be effectively removed. Another advantage is that by adjusting an angle and a distribution of the holes of the gas distribution plate, the cleaning performance can be improved.

According to some embodiments of the present disclosure, a method for operating a semiconductor fabrication apparatus is provided. The method includes performing a deposition process on a wafer in a process chamber; opening the process chamber; and performing a maintenance process when the process chamber is opened. The maintenance process comprises placing a gas distribution plate over a lower chamber portion of the process chamber when the process chamber is open, wherein the gas distribution plate comprises a plurality of holes; and providing a purging gas through the holes of the gas distribution plate to a space surrounded by the lower chamber portion.

According to some embodiments of the present disclosure, a method for operating a semiconductor fabrication apparatus is provided. The method includes performing a plasma process in a process chamber; opening the process chamber; and performing a maintenance process when the process chamber is opened. The maintenance process includes flushing an interior of the process chamber with a purging gas; extracting the purging gas; detecting a particle number in the extracted purging gas; and adjusting the gas force of the purging gas according to the detected particle number.

According to some embodiments of the present disclosure, a semiconductor fabrication apparatus includes a process chamber and a detachable gas supply system. The process chamber includes a lower chamber portion and a top chamber portion. The top chamber portion is separated from the lower chamber portion when the process chamber is open. The detachable gas supply system includes a gas distribution plate and a gas source. The gas distribution plate is detachably placed on the lower chamber portion when the process chamber is open. The gas distribution plate comprises a plurality of holes. The gas source is fluidly connected with the holes of the gas distribution plate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for operating a semiconductor fabrication apparatus, comprising:
performing a deposition process on a wafer in a process chamber;
opening the process chamber; and
performing a maintenance process when the process chamber is opened, wherein the maintenance process comprises:
placing a gas distribution plate over a lower chamber portion of the process chamber when the process chamber is open, wherein the gas distribution plate comprises a plurality of holes; and
providing a purging gas through the holes of the gas distribution plate to a space surrounded by the lower chamber portion.

2. The method of claim 1, further comprising:
after the deposition process and prior to opening the process chamber, moving the wafer away from the process chamber.

3. The method of claim 1, further comprising:
closing the process chamber after the maintenance process.

4. The method of claim 1, wherein the deposition process comprises:
introducing a reactant gas into the process chamber; and
turning the reactant gas into a plasma.

5. The method of claim 1, wherein the maintenance process further comprises:
fluidly connecting a gas extractor to an outlet of the lower chamber portion; and
extracting the purging gas from the space surrounded by the lower chamber portion through the outlet.

6. The method of claim 5, wherein the maintenance process further comprises:
fluidly connecting a particle detector between the gas extractor and the outlet of the lower chamber portion; and
using the particle detector, detecting a particle number in the extracted purging gas.

7. The method of claim 6, wherein the maintenance process further comprises:
adjusting a gas force of the purging gas according to the detected particle number.

8. The method of claim 1, wherein placing the gas distribution plate over the lower chamber portion of the process chamber is performed such that the holes of the gas distribution plate are free of overlapping a wafer chuck in the process chamber in a top view.

9. The method of claim 1, wherein providing the purging gas is performed such that the purging gas is provided through a first one of the holes extending along a first direction and through a second one of the holes extending along a second direction different from the first direction.

10. A method for operating a semiconductor fabrication apparatus, comprising:
performing a plasma process in a process chamber;
opening the process chamber; and
performing a maintenance process when the process chamber is opened, wherein the maintenance process comprises:
flushing an interior of the process chamber with a purging gas;
extracting the purging gas;
detecting a particle number in the extracted purging gas; and
adjusting a gas force of the purging gas according to the detected particle number.

11. The method of claim 10, further comprising:
determining whether the detected particle number is acceptable or not, wherein adjusting the gas force of the purging gas is performed in response the determination determines that the detected particle number is not acceptable.

12. The method of claim 11, further comprising:
terminating flushing the interior of the process chamber with the purging gas in response the determination determines that the detected particle number is acceptable.

13. The method of claim 10, wherein flushing the interior of the process chamber with the purging gas comprises:
placing a gas distribution plate over the process chamber when the process chamber is open, wherein the gas distribution plate comprises a plurality of holes.

14. The method of claim 10, wherein adjusting the gas force of the purging gas comprises:
tuning the gas force of the purging gas to be a first gas force when the detected particle number is in a first range; and
tuning the gas force of the purging gas to be a second gas force greater than the first gas force when the detected particle number is in a second range greater than the first range.

15. A semiconductor fabrication apparatus, comprising:
a process chamber comprising a lower chamber portion and a top chamber portion, wherein the top chamber portion is separated from the lower chamber portion when the process chamber is open; and
a detachable gas supply system, comprising:
a gas distribution plate detachably placed on the lower chamber portion when the process chamber is open, wherein the gas distribution plate comprises a plurality of holes; and
a gas source fluidly connected with the holes of the gas distribution plate.

16. The semiconductor fabrication apparatus of claim 15, wherein a first one of the holes extends along a first direction, and a second one of the holes extends along a second direction different from the first direction.

17. The semiconductor fabrication apparatus of claim 15, wherein a third one of the holes extends along a third direction different from the first and second directions.

18. The semiconductor fabrication apparatus of claim 15, wherein one of the holes extending along a direction, and an angle between the direction and a bottom surface of the gas distribution plate is in a range from about 40 degrees to about 50 degrees.

19. The semiconductor fabrication apparatus of claim 15, further comprising:
a wafer chuck in the process chamber, wherein the holes of the gas distribution plate are free of overlapping the wafer chuck in a top view.

20. The semiconductor fabrication apparatus of claim 15, further comprising:
a detachable gas exhaust system, comprising:
a gas extractor fluidly connected with an outlet of the lower chamber portion; and
a particle detector fluidly connected between the gas extractor and the outlet of the lower chamber portion.
